(19) United States
(12) Patent Application Publication
(10) Pub. No.: US 2019/0362968 A1
(43) Pub. Date: Nov. 28, 2019

(54) METHOD OF PRODUCING SEMICONDUCTOR NANOPARTICLE

(71) Applicants: HITACHI CHEMICAL COMPANY, LTD., Tokyo (JP); National Institute of Advanced Industrial Science and Technology, Tokyo (JP)

(72) Inventors: Shori KOSUDA, Chiyoda-ku, Tokyo (JP); Yusuke MABUCHI, Chiyoda-ku, Tokyo (JP); Masahiko HIRATANI, Chiyoda-ku, Tokyo (JP); Taizo SANO, Tsukuba-shi, Ibaraki (JP); Akihiro WAKISAKA, Tsukuba-shi, Ibaraki (JP)

(21) Appl. No.: 16/480,468

(22) PCT Filed: Jan. 23, 2018
(86) PCT No.: PCT/JP2018/001978

§ 371 Date: Jul. 24, 2019

(30) Foreign Application Priority Data
Jan. 25, 2017 (JP) 2017-011180

(51) Int. Cl. H01L 21/02; C09K 11/88; C09K 11/62

(52) U.S. Cl. CPC H01L 21/02601; H01L 21/02543; B82Y 40/00; C09K 11/62; H01L 21/02628; C09K 11/883

(57) ABSTRACT

A method of producing a semiconductor nanoparticle, the method producing an indium- and phosphorus-containing semiconductor nanoparticle, in which the method includes preparing an indium-containing liquid (1) and a phosphorus-containing liquid (2), and spraying one of the liquid (1) or the liquid (2) from a spray unit in an inert gas and bringing a sprayed liquid droplet into contact with another liquid of the liquid (1) or the liquid (2), which is not sprayed, thereby mixing the liquid (1) and the liquid (2) to allow at least indium and phosphorus to react.

### TECHNICAL FIELD

The present invention relates to a method of producing a semiconductor nanoparticle.

### BACKGROUND ART

Semiconductor nanoparticles such as semiconductor quantum dots have excellent fluorescent properties, and have been progressively applied to displays, illuminations, biosensing, and the like. Semiconductor quantum dots have also been progressively studied as materials for enhancing the efficiency of solar cells. In particular, semiconductor quantum dots including Group 12 elements or Group 13 elements, and 15 Group elements or Group 16 elements can possibly serve as excellent fluorescent materials, and examples of such semiconductor quantum dots include cadmium selenide (CdSe) and indium phosphide (InP). The fluorescence wavelengths of semiconductor quantum dots are changed depending on the particle sizes, and thus can be controlled by control of the particle sizes. A narrower particle size distribution can allow a fluorescence peak to have a narrower half-value width, thereby providing a high-purity color. Thus, a method of producing a semiconductor quantum dot, which can allow for control to any particle size, is required.

For example, a solvothermal method is proposed as a method of producing a semiconductor quantum dot. Such a solvothermal method includes mixing a metal ion precursor and a negative ion precursor in a coordinating organic solvent and heating the mixture, thereby synthesizing a semiconductor quantum dot.

An exemplary solvothermal method is a method of producing indium phosphide, the method including placing indium chloride, tris(dimethylamino)phosphine, dodecylamine, and toluene in an airtight container, blowing argon and then sealing the container, and protecting the container by a stainless jacket and heating it at 180° C. for 24 hours (see, for example, Patent Document 1). The method provides indium phosphide having a broad particle size distribution and also exhibiting a broad fluorescence spectrum.

### CITATION LIST

### Patent Document

Patent Document 1: Japanese Patent Application Laid-Open (JP-A) No. 2010-138367

### SUMMARY OF INVENTION

### Technical Problem

A semiconductor nanoparticle produced by a solvothermal method has a broad particle size distribution, and is required to be subjected to particle sorting in order that a semiconductor nanoparticle having only a specified fluorescence wavelength is obtained. Such sorting causes many organic solvents and times to be required, and also causes the material yield to be deteriorated. Furthermore, indium phosphide obtained by a solvothermal method has a fluorescence peak wavelength of, for example, from about 620 nm to 640 nm, and a problem is that the production efficiency of indium phosphide where the fluorescence wavelength is a short wavelength (for example, 570 nm or less, preferably 550 nm or less), obtained by classification, is very low. Thus, a method that can efficiently produce indium phosphide where the fluorescence peak wavelength is a long wavelength to a short wavelength, namely, a method that can efficiently produce indium phosphide having a desired fluorescence peak wavelength is desirable.

An object of one aspect of the invention is to provide a method of producing a semiconductor nanoparticle, which can efficiently produce indium phosphide having a desired fluorescence peak wavelength.

### Solution to Problem

Solutions to solve the above problems include the following aspects.

<1> A method of producing a semiconductor nanoparticle, the method producing an indium- and phosphorus-containing semiconductor nanoparticle, the method comprising: preparing an indium-containing liquid (1) and a phosphorus-containing liquid (2), and spraying one of the liquid (1) or the liquid (2) from a spray unit in an inert gas and bringing a sprayed liquid droplet into contact with another liquid of the liquid (1) or the liquid (2), which is not sprayed, thereby mixing the liquid (1) and the liquid (2) to allow indium and phosphorus to react.
<2> A method of producing a semiconductor nanoparticle, the method producing an indium- and phosphorus-containing semiconductor nanoparticle, the method comprising: spraying an indium- and phosphorus-containing liquid (3) from a spray unit in an inert gas and bringing a sprayed liquid droplet into contact with a liquid (4), thereby mixing the liquid (3) and the liquid (4) to allow indium and phosphorus to react.
<3> The method of producing a semiconductor nanoparticle according to <1> or <2>, wherein the spraying is performed by electrospray.
<4> The method of producing a semiconductor nanoparticle according to <3>, wherein the spraying by the electrospray is performed with a potential difference being provided between a first electrode, which forms at least a part of a flow path for a liquid to be sprayed, or which is attached to at least a part of the flow path, and a second electrode which is disposed at a position where the liquid droplet is brought into contact with a liquid to be sprayed.
<5> The method of producing a semiconductor nanoparticle according to <4>, wherein the potential difference between the first electrode and the second electrode is from 0.3 kV to 30 kV, as an absolute value.
<6> The method of producing a semiconductor nanoparticle according to any one of <1> to <5>, wherein a diameter of the sprayed liquid droplet is from 0.1 μm to 100 μm.
<7> The method of producing a semiconductor nanoparticle according to any one of <1> to <6>, wherein: the semiconductor nanoparticle has a core particle comprising indium and phosphorus, and a layer comprising a Group 16 element and at least one of a Group 12 element or a Group 13 element is formed on at least a part of a surface of the core particle, after formation of the core particle.
<8> The method of producing a semiconductor nanoparticle according to any one of <1> to <7>, wherein a width of a spray port in the spray unit is from 0.03 mm to 2.0 mm.
<9> The method of producing a semiconductor nanoparticle according to any one of <1> to <8>, wherein a feeding rate of the liquid to be sprayed is from 0.001 mL/min to 1 mL/min with respect to one flow path provided with the spray unit.
<10> The method of producing a semiconductor nanoparticle according to any one of <1> to <9>, wherein an indium- and phosphorus-containing liquid is heated in the reaction of indium and phosphorus.
<11> The method of producing a semiconductor nanoparticle according to <10>, wherein a heating temperature of the indium- and phosphorus-containing liquid is from 80° C. to 350° C.
<12> The method of producing a semiconductor nanoparticle according to any one of <1> to <11>, wherein a molar ratio of an indium atom and a phosphorus atom (indium atom:phosphorus atom) in an indium- and phosphorus-containing liquid is from 1:1 to 1:16 after spraying of the liquid droplet.

### Advantageous Effect of Invention

One aspect of the invention can provide a method of producing a semiconductor nanoparticle, which can efficiently produce indium phosphide having a desired fluorescence peak wavelength.

### BRIEF DESCRIPTION OF DRAWINGS

FIG. 1 is a schematic view illustrating a production apparatus for use in the method of producing a semiconductor nanoparticle of the present disclosure.

FIG. 2 is a graph illustrating the relationship between the synthesis temperature, and the fluorescence peak wavelength and the half-value width, with respect to any semiconductor nanoparticle in Examples 1 to 6.

FIG. 3 is a graph illustrating the relationship between the spray voltage, and the fluorescence peak wavelength and the half-value width, with respect to any semiconductor nanoparticle in Examples 7 to 11, and Examples 18 and 19.

FIG. 4 is a graph illustrating the relationship between the molar ratio of indium and phosphorus, and the fluorescence peak wavelength and the half-value width, with respect to any semiconductor nanoparticle in Examples 12 to 17.

FIG. 5 is a graph illustrating the relationship between the diameter of a spray port, and the fluorescence peak wavelength and the half-value width, in Examples 20 to 25.

### DESCRIPTION OF EMBODIMENTS

Hereinafter, modes for carrying out the invention will be described in detail. It is noted that the invention is not intended to be limited to the following embodiments. Any components (also including elemental steps and the like) are not essential in the following embodiments, unless particularly clearly specified. Any numerical values and ranges thereof are not similarly essential and are not intended to limit the invention.

A numerical value range represented by use of “(from) . . . to . . . ” in the disclosure means that numerical values described before and after “to” are included as a minimum value and a maximum value, respectively.

An upper limit or a lower limit described in one numerical value range as a numerical value range step-wisely described in the disclosure may be replaced with an upper limit or a lower limit of other numerical value range step-wisely described. An upper limit or a lower limit described in a numerical value range described in the disclosure may be replaced with any value indicated in Examples.

### First Embodiment

### [Method of Producing Semiconductor Nanoparticle]

The method of producing a semiconductor nanoparticle of the disclosure produces an indium- and phosphorus-containing semiconductor nanoparticle, with including preparing an indium-containing liquid (1) (hereinafter, also referred to as “liquid (1)”.) and a phosphorus-containing liquid (2) (hereinafter, also referred to as “liquid (2)”.), and spraying one of the liquid (1) or the liquid (2) from a spray unit in an inert gas and bringing a sprayed liquid droplet into contact with another liquid of the liquid (1) or the liquid (2), which is not sprayed, thereby mixing the liquid (1) and the liquid (2) to allow at least indium and phosphorus to react.

The method of producing a semiconductor nanoparticle of the disclosure involves spraying one of an indium-containing liquid (1) or a phosphorus-containing liquid (2) from a spray unit in an inert gas, and bringing a sprayed liquid droplet into contact with another liquid of the liquid (1) or the liquid (2), which is not sprayed. Both the liquids are brought into contact with each other and mixed, to allow at least indium and phosphorus to react, thereby producing an indium- and phosphorus-containing semiconductor nanoparticle. The sprayed liquid droplet, as one of the liquid (1) or the liquid (2), is brought into contact with the other liquid, thereby producing an indium- and phosphorus-containing semiconductor nanoparticle, whereby a semiconductor nanoparticle to be produced is easily controlled with respect to the particle size and a semiconductor nanoparticle to be produced is easily controlled with respect to the fluorescence wavelength (for example, fluorescence wavelength at a shorter wavelength), as compared with the case of a solvothermal method. Accordingly, a semiconductor nanoparticle where the fluorescence peak wavelength is a long wavelength to a short wavelength can be selectively efficiently produced, and a semiconductor nanoparticle having a desired fluorescence peak wavelength can be efficiently produced.

For example, a semiconductor nanoparticle where the fluorescence wavelength is a short wavelength (for example, 570 nm or less, preferably 550 nm or less) tends to be able to be efficiently produced.

A “semiconductor nanoparticle” in the disclosure means any particle having an average particle size of from 1 nm to 100 nm. The average particle size of a semiconductor nanoparticle here corresponds to a particle size (D50) where the accumulation from the smaller size reaches 50% in a particle size distribution on a volume basis, as measured according to a laser diffraction method.

The shape of a “semiconductor nanoparticle” in the disclosure is not particularly limited, and may be a spherical shape, an oval-spherical shape, a flake shape, a rectangular solid shape, a columnar shape, an irregular shape or the like, or may be a spherical shape, an oval-spherical shape, a flake shape, a rectangular solid shape, a columnar shape or the like which partially has an irregular shape.

A “semiconductor nanoparticle” in the disclosure may contain at least indium and phosphorus, and, for example, may have a layer including a Group 16 element and at least one of a Group 12 element or a Group 13 element on at least a part of a surface thereof or may be one into which any atom, molecule, and the like contained in a dispersant, other organic solvent, an indium compound, a phosphorus compound, and the like are incorporated during a process of producing a semiconductor nanoparticle.

The indium-containing liquid (1) for use in the method of producing a semiconductor nanoparticle may be any liquid containing an indium source, and, for example, may be any liquid containing at least one of metallic indium or an indium compound. One example thereof may be a solution where an indium compound such as indium chloride is heated and dissolved in a dispersant such as oleylamine. A solid may be precipitated at ordinary temperature (25° C.).

The indium compound is not particularly limited as long as the compound includes an indium element, examples thereof include indium halide such as indium chloride, indium bromide, or indium iodide, indium oxide, indium nitride, indium sulfide, indium hydroxide, indium acetate, and indium isopropoxide, and, in particular, indium chloride is preferable because it is rich in reactivity with a phosphorus compound (for example, tris(dimethylamino)phosphine) and is relatively inexpensive in market price.

The indium-containing liquid (1) preferably includes a dispersant from the viewpoint of suppression of aggregation of the indium compound or the like in the liquid. The dispersant is preferably a coordinating organic solvent, specific examples thereof include an organic amine such as dodecylamine, tetradecylamine, hexadecylamine, oleylamine, trioctylamine, or eicocylamine, a fatty acid such as lauric acid, caproic acid, myristic acid, palmitic acid, or oleic acid, and an organic phosphine oxide such as trioctylphosphine oxide, and, in particular, oleylamine is preferable because it is excellent in reactivity with a phosphorus compound, has the property of promoting generation of indium phosphide, and has a high boiling point and thus is hardly volatilized even in synthesis at high temperatures.

In a case in which the indium-containing liquid (1) contains the dispersant, the total content of the metallic indium and the indium compound with respect to 1 mL of the dispersant is preferably from 0.01 g to 0.2 g, more preferably from 0.03 g to 0.15 g, still more preferably from 0.05 g to 0.10 g.

The indium-containing liquid (1) may contain other organic solvent. Examples of such other organic solvent include an aliphatic saturated hydrocarbon such as n-hexane, n-heptane, n-octane, n-nonane, n-decane, n-dodecane, n-hexadecane, or n-octadecane, an aliphatic unsaturated hydrocarbon such as 1-undecene, 1-dodecene, 1-hexadecene, or 1-octadecene, and trioctylphosphine.

The phosphorus-containing liquid (2) for use in the method of producing a semiconductor nanoparticle may be a liquid containing a phosphorus source, and, for example, may be a liquid containing single phosphorus or a phosphorus compound. In a case in which the phosphorus compound is a solid, a solution of the phosphorus compound in a dispersant such as oleylamine may be adopted as the phosphorus-containing liquid (2). In a case in which the phosphorus compound is a liquid, a single phosphorus compound or a mixture of a phosphorus compound with a dispersant such as oleylamine may be adopted as the phosphorus-containing liquid (2).

The phosphorus compound is not particularly limited as long as the phosphorus compound contains a phosphorus element, examples thereof include tris(dimethylamino)phosphine, tris(diethylamino)phosphine, tris(trimethylsilyl)phosphine, and phosphine (PH₃), and, in particular, tris(dimethylamino)phosphine is preferable because, for example, it is rich in reactivity with an indium ion, is a liquid having a high boiling point and thus is suitable for synthesis at high temperatures, and is low in toxicity as compared with, for example, a silyl-type phosphorus compound.

Examples of the dispersant include those for use in the indium-containing liquid (1). The phosphorus-containing liquid (2) may contain other organic solvent described above, as in the indium-containing liquid (1).

In a case in which the phosphorus-containing liquid (2) contains the dispersant, the content of the phosphorus compound with respect to 1 mL of the dispersant is preferably from 0.1 g to 0.5 g, more preferably from 0.15 g to 0.4 g, still more preferably from 0.2 g to 0.3 g.

The method of producing a semiconductor nanoparticle of the disclosure includes spraying one of the liquid (1) or the liquid (2) from a spray unit in an inert gas and bringing a sprayed liquid droplet into contact with another liquid of the liquid (1) or the liquid (2), which is not sprayed. Thus, incorporation of oxygen, steam, or the like into a semiconductor nanoparticle to be produced tends to be suppressed, the occurrence of defects on such a semiconductor nanoparticle tends to be suppressed, and a reduction in fluorescence efficiency tends to be suppressed.

Examples of the inert gas include nitrogen, argon, carbon dioxide, sulfur hexafluoride (SF), and a mixed gas thereof.

The method of producing a semiconductor nanoparticle of the disclosure preferably includes spraying the liquid (2) from a spray unit in the inert gas and bringing a sprayed liquid droplet into contact with the liquid (1), from the viewpoint of more efficient production of a semiconductor nanoparticle.

The method of producing a semiconductor nanoparticle of the disclosure also preferably includes spraying one of the liquid (1) or the liquid (2) by electrospray. Thus, the particle size of a semiconductor nanoparticle tends to be able to be suitably controlled and a semiconductor nanoparticle having a desired fluorescence peak wavelength tends to be able to be more efficiently produced.

In the disclosure, “electrospray” refers to an apparatus that applies a voltage between electrodes to form electric field and sprays a liquid by a Coulomb's force, or refers to a state where a liquid is sprayed by the apparatus.

It is preferable to use a first electrode which forms at least a part of a flow path (for example, nozzle) for a liquid to be sprayed, or which is attached to at least a part of the flow path, and a second electrode which is disposed at a position where the liquid droplet is brought into contact with a liquid to be sprayed, in the spraying by the electrospray.

The first electrode and the second electrode are for forming a static electric field therebetween by application of a voltage. Examples of the shape of the second electrode include a substantially ring shape, a substantially cylindrical shape, a substantially mesh shape, a substantially rod shape, a substantially spherical shape, and a substantially semi-spherical shape.

The potential difference (spray voltage) between the first electrode and the second electrode in spraying by the electrospray is preferably from 0.3 kV to 30 kV, more preferably from 1.0 kV to 10 kV, as an absolute value.

The spray voltage is preferably from 1.0 kV to less than 8.0 kV from the viewpoint of more efficient production of a semiconductor nanoparticle where the fluorescence wavelength is a short wavelength, in particular, more efficient production of a semiconductor nanoparticle where the fluorescence wavelength is from 500 nm to 550 nm.

The spray voltage is preferably less than 2.0 kV or 4.0 kV or more, more preferably from 5.0 kV to 10.0 kV, still more preferably from 6.0 kV to 10.0 kV from the viewpoint of more efficient production of a semiconductor nanoparticle having a narrow particle size distribution.

The diameter of the sprayed liquid droplet is preferably from 0.1 μm to 100 μm, more preferably from 1 μm to 50 μm, still more preferably from 1 μm to 10 μm from the viewpoint of more efficient production of a semiconductor nanoparticle having a desired fluorescence peak wavelength. In a case in which the diameter of the sprayed liquid droplet falls within the numerical value range, the change in liquid temperature in the contact of a liquid droplet to be sprayed, with other liquid not sprayed, and thus mixing of the liquid (1) and the liquid (2) tends to be able to be suppressed to allow the temperature of the sprayed liquid droplet and the temperature of other liquid not sprayed to be the same in a short time. Thus, the change in temperature of the reaction field for the reaction of indium and phosphorus tends to be able to be small, thereby allowing the particle size of a semiconductor nanoparticle to be suitably controlled, and allowing a semiconductor nanoparticle where the fluorescence wavelength is a short wavelength to be further efficiently produced.

The diameter of the sprayed liquid droplet can be appropriately adjusted by, for example, adjusting the size of the spray unit that sprays the liquid droplet (the width of the spray port, or the like), adjusting the feeding rate, surface tension, viscosity, ionic strength, and relative permittivity of the liquid to be sprayed, adjusting a voltage in spraying by the electrospray, and/or adjusting the type of the inert gas.

The width of the spray port in the spray unit that sprays the liquid droplet is preferably from 0.03 mm to 2.0 mm, more preferably from 0.03 mm to 1.5 mm, still more preferably from 0.05 mm to 1.0 mm, particularly preferably from 0.07 mm to 0.70 mm, much more preferably from 0.08 to 0.60 mm, still further preferably from 0.25 mm to 0.40 mm.

The spray port refers to a portion where the liquid droplet is outwardly sprayed. The shape of the spray port may be a circular shape, a multangular shape or the like, or may be a zigzag shape, a wave shape, a brush shape or the like when viewed from the side surface. The width of the spray port refers to a length where the distance between two faces in parallel with each other is the maximum in sandwiching of the periphery of the spray port between such two faces. In a case in which the spray port has a circular shape, the width of the spray port refers to the diameter of the spray port.

The feeding rate of the liquid to be sprayed is preferably from 0.001 mL/min to 1 mL/min, more preferably from 0.01 mL/min to 0.1 mL/min, still more preferably from 0.02 mL/min to 0.05 mL/min, with respect to one flow path (for example, nozzle) provided with the spray unit that sprays the liquid droplet.

For example, in a case in which the liquid droplet is sprayed from one nozzle, the feeding rate of the liquid through the nozzle preferably satisfies the numerical value range. In a case in which the liquid droplet is sprayed from a plurality of nozzles, all the feeding rates of the liquid through the plurality of nozzles preferably satisfy the numerical value range.

The distance between the spray port as the tip of the spray unit that sprays the liquid as one of the liquid (1) or the liquid (2) and the liquid level of another liquid of the liquid (1) or the liquid (2), which is not sprayed is preferably from 2 mm to 100 mm, more preferably from 5 mm to 70 mm, still more preferably from 10 mm to 50 mm, from the viewpoint of suppression of the variation in shape of the sprayed liquid droplet.

In a case in which the liquid (1) and the liquid (2) are mixed to allow at least indium and phosphorus to react, an indium- and phosphorus-containing liquid is preferably heated from the viewpoint of more efficient production of the semiconductor nanoparticle.

The heating temperature of the indium- and phosphorus-containing liquid is not particularly limited, is preferably from 80° C. to 350° C., and is more preferably from 100° C. to 220° C., still more preferably from 120° C. to 190° C. from the viewpoint of more efficient production of a semiconductor nanoparticle where the fluorescence wavelength is a short wavelength.

The molar ratio of an indium atom and a phosphorus atom (indium atom:phosphorus atom) in the indium- and phosphorus-containing liquid after spraying of the liquid droplet is preferably from 1:1 to 1:16 from the viewpoint of more efficient production of a semiconductor nanoparticle where the fluorescence wavelength is a short wavelength, and is more preferably more than 1:2 but less than 1:8, still more preferably from 1:3 to 1:7, particularly preferably from 1:4 to 1:6 from the viewpoint of more efficient production of a semiconductor nanoparticle having a narrower particle size distribution.

In the method of producing a semiconductor nanoparticle of the disclosure, such a semiconductor nanoparticle may have a core particle including at least indium and phosphorus, and a layer (shell layer) including a Group 16 element and at least one of a Group 12 element or a Group 13 element, which is formed on at least a part of a surface of the core particle, after formation of the core particle. Thus, the quantum efficiency of a semiconductor nanoparticle tends to be able to be more enhanced, or the particle size distribution of a semiconductor nanoparticle tends to be able to be narrower. The shell layer to be formed on at least a part of a surface of the core particle may have a monolayer structure or a multi-layer structure (core-multishell structure).

Examples of such a Group 12 element include zinc and cadmium, examples of such a Group 13 element include gallium, and examples of such a Group 16 element include oxygen, sulfur, selenium, and tellurium. The layer to be formed on at least a part of a surface of the core particle preferably includes zinc, more specifically CdS, CdSe, CdTe, ZnS, ZnSe, ZnTe, ZnO, InGaZnO, or the like, and, in particular, ZnS is preferable.

The method of forming the shell layer including a Group 16 element and at least one of a Group 12 element or a Group 13 element on at least a part of a surface of the core particle is not particularly limited. For example, the shell layer may be formed by forming a particle including at least indium and phosphorus (core particle) as described above, thereafter adding a substance serving as a supply source of at least one of a Group 12 element or a Group 13 element and a substance serving as a supply source of a Group 16 element to a liquid including the particle and, if necessary, further adding a solvent thereto, and then heating the liquid with stirring. Thus, a semiconductor nanoparticle having the shell layer including a Group 16 element and at least one of a Group 12 element or a Group 13 element can be produced on at least a part of a surface of the core particle.

In a case in which the Group 12 element is zinc, examples of a substance serving as a supply source of zinc include a zinc compound, more specifically zinc stearate or zinc halide such as zinc chloride.

In a case in which the Group 16 element is sulfur, examples of a substance serving as a supply source of sulfur include a sulfur compound, more specifically a thiol compound such as dodecanethiol or tetradecanethiol and a sulfide compound such as dihexyl sulfide. Such a supply source of sulfur may be herein one where sulfur is dissolved in trioctylphosphine.

Examples of the solvent, if necessary, used include other organic solvent described above, and, in particular, 1-octadecene is preferable.

The substance serving as a supply source of at least one of a Group 12 element or a Group 13 element or the substance serving as a supply source of a Group 16 element may be contained in at least one of the indium-containing liquid (1) or the phosphorus-containing liquid (2). In a case in which the substance serving as a supply source of at least one of a Group 12 element or a Group 13 element is contained in at least one of the liquid (1) or the liquid (2), a particle including at least indium and phosphorus (core particle) may be formed as described above, thereafter the substance serving as a supply source of a Group 16 element may be added to a liquid including the particle and the resultant may be subjected to the same operation as described above. In a case in which the substance serving as a supply source of a Group 16 element is contained in at least one of the liquid (1) or the liquid (2), a particle including at least indium and phosphorus (core particle) may be formed as described above, thereafter the substance serving as a supply source of at least one of a Group 12 element or a Group 13 element may be added to a liquid including the particle and the resultant may be subjected to the same operation as described above.

In formation of a layer (shell layer) including a Group 16 element and at least one of a Group 12 element or a Group 13 element on at least a part of a surface of the core particle, the reaction temperature is preferably from 150° C. to 350° C., more preferably from 150° C. to 300° C., and the reaction time is preferably from 1 hour to 200 hours, more preferably from 2 hours to 100 hours, still more preferably from 3 hours to 25 hours.

### Second Embodiment

### [Method of Producing Semiconductor Nanoparticle]

The method of producing a semiconductor nanoparticle of the disclosure may produce an indium- and phosphorus-containing semiconductor nanoparticle, with including spraying an indium- and phosphorus-containing liquid (3) (hereinafter, also referred to as “liquid (3)”.) from a spray unit in an inert gas and bringing a sprayed liquid droplet into contact with a liquid (4), thereby mixing the liquid (3) and the liquid (4) to allow at least indium and phosphorus to react. The first embodiment and the second embodiment are different from each other in that, while the method of producing a semiconductor nanoparticle of the first embodiment allows one of indium or phosphorus to be contained in both a liquid to be sprayed and a liquid to be brought into contact with the liquid sprayed, the method of producing a semiconductor nanoparticle of the second embodiment allows both indium and phosphorus to be contained in a liquid to be sprayed. The second embodiment can also allow for selective and efficient production of a semiconductor nanoparticle where the fluorescence peak wavelength is a long wavelength to a short wavelength, and efficient production of a semiconductor nanoparticle having a desired fluorescence peak wavelength.

Hereinafter, any items different from those in the first embodiment will be mainly described, and the description of any items similar to those in first embodiment will be omitted.

The indium- and phosphorus-containing liquid (3) preferably contains the dispersant from the viewpoint of suppression of aggregation of an indium compound or the like in a liquid.

In a case in which the indium- and phosphorus-containing liquid (3) contains the dispersant, the total content of the metallic indium and the indium compound with respect to 1 mL of the dispersant is preferably from 0.01 g to 0.2 g, more preferably from 0.03 g to 0.15 g, still more preferably from 0.05 g to 0.10 g.

The liquid (4) is not particularly limited, and may include the dispersant, other organic solvent, and the like.

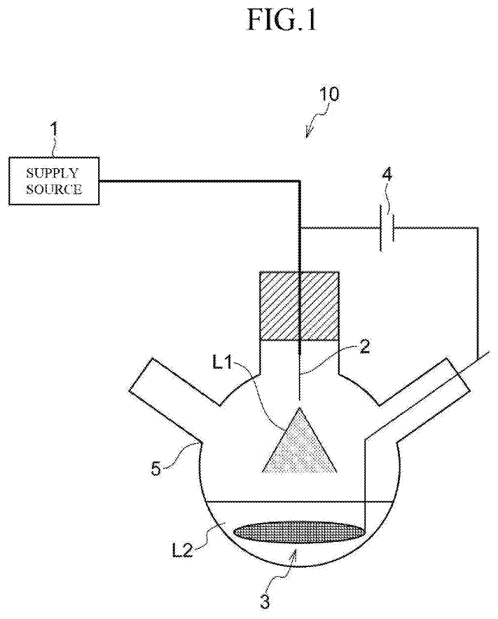

Next, one example of the method of producing a semiconductor nanoparticle of the disclosure by use of a production apparatus illustrated in FIG. 1 will be described. FIG. 1 is a schematic view illustrating a production apparatus for use in the method of producing a semiconductor nanoparticle of the disclosure.

A production apparatus 10 illustrated in FIG. 1 includes a supply source 1 of a liquid to be sprayed, a spray unit 2 also serving as a first electrode, a mesh-shaped opposite electrode 3 serving as a second electrode, a power source 4 serving as a voltage application unit, and a reactor 5 including at least an end of the spray unit 2 and the opposite electrode 3 therein.

The supply source 1 supplies a liquid to be sprayed, to the spray unit 2. For example, a phosphorus-containing liquid (2) is supplied to the spray unit 2 from the supply source 1. The opposite electrode 3 is disposed in the reactor 5, and a liquid L2 as an indium-containing liquid (1) is stored in the reactor so as to be in contact with the opposite electrode 3. The reactor 5 is filled with an inert gas.

Such an inert gas may be herein allowed to flow through the reactor 5 at any value of more than 0 L/min but equal to or less than 10 L/min in terms of the gas flow rate with respect to one inert gas supply unit which supplies the inert gas into the reactor 5.

The spray unit 2 is configured to be able to electrostatically spray a liquid supplied from the supply source 1. The phosphorus-containing liquid (2) supplied from the supply source 1 is sprayed in the form of a fine liquid droplet L1 through a spray port of the spray unit 2. The spray unit 2 serving as a first electrode is here preferably disposed so as to allow the fine liquid droplet L1 to be sprayed in a direction perpendicular to a plane surface of the opposite electrode 3.

The power source 4 is a high-voltage power source which is electrically connected to both the spray unit 2 and the opposite electrode 3. The power source 4 may be configured such that the spray unit 2 is at a positive potential and the opposite electrode 3 is lower in potential than that of the spray unit 2, or may be configured such that the spray unit 2 is at a negative potential and the opposite electrode 3 is higher in potential than that of the spray unit 2.

The fine liquid droplet L1 is sprayed through the spray port of the spray unit 2 with a static electric field being formed between the spray unit 2 and the opposite electrode 3 due to voltage application from the power source 4 to the spray unit 2 and the opposite electrode 3. Thus, the fine liquid droplet L1, with being charged, is moved toward the liquid L2 along with the electric field gradient, and is brought into contact with the liquid level of the liquid L2. Both the liquids are brought into contact with each other and mixed, to allow at least indium and phosphorus to react, thereby producing an indium- and phosphorus-containing semiconductor nanoparticle. The semiconductor nanoparticle produced is dispersed in the liquid L2, thereby allowing a dispersion liquid of the semiconductor nanoparticle to be obtained.

The fine liquid droplet L1 may be sprayed with the liquid L2 being stirred.

For example, a semiconductor nanoparticle produced by adding toluene to a dispersion liquid taken out from the reactor 5, subsequently gradually adding methanol thereto, and subjecting a suspended substance precipitated, to centrifugation, may be classified and the semiconductor nanoparticle classified may be recovered.

The liquid L2 stored in the reactor 5 is preferably heated by a heating unit (not illustrated) such as an oil bath, an aluminum bath, a mantle heater, an electric furnace, or an infrared furnace from the viewpoint of control of the particle size of an indium- and phosphorus-containing semiconductor nanoparticle to be produced and also efficient production of such a semiconductor nanoparticle.

Such a semiconductor nanoparticle may also be obtained by forming a shell layer including a Group 16 element and at least one of a Group 12 element or a Group 13 element on at least a part of a surface of a particle produced in the production apparatus 10.

The invention is not limited to the method of producing a semiconductor nanoparticle, including storing a liquid in a reactor and spraying a liquid droplet to the liquid stored, as described above. For example, the method may include allowing a liquid to flow through a reactor, spraying a liquid droplet to the liquid allowed to flow therethrough, thereby producing a semiconductor nanoparticle, and recovering the semiconductor nanoparticle produced, in each case. Thus, a semiconductor nanoparticle can be continuously produced.

The method of producing a semiconductor nanoparticle of the disclosure can be applied to production of a fluorescent material for various liquid crystal displays, and can also be applied to manufacturing of various electronic devices on which a liquid crystal display is mounted.

### EXAMPLES

Hereinafter, the invention will be specifically described with reference to Examples, but the scope of the invention is not intended to be limited to such Examples.

### Examples 1 to 6

Indium phosphide was synthesized at a temperature shown in Table 1 and an outer shell (shell layer) of zinc sulfide was formed on a surface of the indium phosphide synthesized, by use of the producing method of the first embodiment, and thereafter a fluorescence spectrum was measured. Indium chloride and tris(dimethylamino)phosphine were used for raw materials, and oleylamine was used for a dispersant.

The Examples were performed as follows. First, 0.3 g of indium chloride was weighed in a reaction container made of glass, and 5 mL of oleylamine was added thereto and mixed therewith. The operation was performed under a dry nitrogen atmosphere in order to prevent moisture absorption of the indium chloride. Subsequently, heating to 120° C. was made in an oil bath with nitrogen being allowed to flow through the reaction container, and the indium chloride was dissolved in the oleylamine. Subsequently, the reaction container was heated to a temperature shown in Table 1, in an oil bath, and 1.05 mL of tris(dimethylamino)phosphine (at a rate of 0.050 mL/min for 21 minutes) was sprayed by electrospray from a stainless tube (spray unit) whose tip was adapted to be located at a distance of 3.5 cm from the liquid level and which had an inner diameter of 0.5 mm. The spray voltage was 6.0 kV. Thereafter, the resultant was cooled to room temperature, thereby providing an indium phosphide-containing solution sample.

In order to facilitate the comparison of fluorescent properties, 0.7 g of zinc stearate, 2.6 mL of dodecanethiol and 2.4 mL of 1-octadecene as a solvent were added to 1 mL of each solution sample obtained as described above, and the resultant was heated in an autoclave at 180° C. for 20 hours, thereby forming an outer shell (shell layer) of zinc sulfide on the surface of the indium phosphide. Thereafter, the resultant was cooled to room temperature, thereby providing a solution sample containing each indium phosphide (S02 to S07) where the outer shell of zinc sulfide was formed on the surface.

(Measurement of Fluorescence Peak Wavelength and Half-Value Width)

A dispersion liquid of a semiconductor nanoparticle of indium phosphide was obtained by adding 3 mL of hexane to such a solution sample containing each indium phosphide on which the outer shell of zinc sulfide was formed.

The resulting dispersion liquid of a semiconductor nanoparticle of indium phosphide was subjected to measurement of a fluorescence spectrum under irradiation with light at 450 nm by use of a fluorescence spectrophotometer (RF-5300 manufactured by Shimadzu Corporation), and the fluorescence peak wavelength and the half-value width were determined.

The half-value width means a full width at half maximum (FWHM), corresponding to a peak width at a height of half the peak height.

The results are shown in Table 1.

### Comparative Example 1

Indium phosphide was synthesized according to a solvothermal method, an outer shell (shell layer) of zinc sulfide was formed on a surface of the indium phosphide synthesized, and thereafter a fluorescence spectrum was measured.

First, indium chloride, tris(dimethylamino)phosphine, dodecylamine, and toluene was placed in an airtight container made of polytetrafluoroethylene, nitrogen was blown and also the container was sealed, and the container was protected by a stainless jacket and heated at 180° C. for 24 hours, thereby producing indium phosphide. Thereafter, an outer shell (shell layer) of zinc sulfide was formed on the surface of the indium phosphide, and the fluorescence peak wavelength and the half-value width were measured, in the same manner as in Examples 1 to 6 described above.

The results are shown in Table 1.

TABLE 1

| | | Synthesis | | |
|---|---|---|---|---|
| | Sample | temperature | Fluorescence peak | Half-value |
| | number | ° C. | wavelength | width nm |
| Example 1 | S02 | 120 | 480 | 48 |
| Example 2 | S03 | 140 | 485 | 50 |
| Example 3 | S04 | 160 | 495 | 55 |
| Example 4 | S05 | 180 | 505 | 78 |
| Example 5 | S06 | 200 | 557 | 89 |
| Example 6 | S07 | 220 | 560 | 86 |
| Comparative | S01 | 180 | 630 | 90 |
| Example 1 | | | | |

As shown in Table 1, the respective semiconductor nanoparticles (S02 to S07) produced in Example 1 to Example 6 had a shorter fluorescence peak wavelength and a smaller half-value width than the semiconductor nanoparticle (S01) produced in Comparative Example 1.

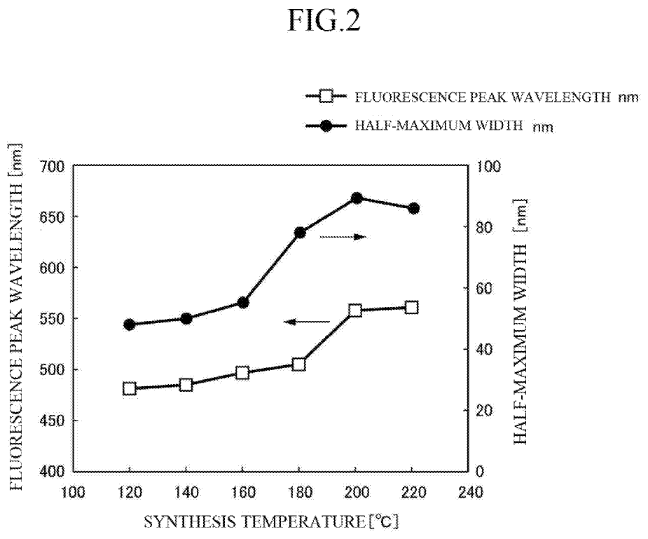

In particular, as illustrated in FIG. 2, a fluorescence peak at 525±20 nm was obtained in measurement of a fluorescence spectrum of the semiconductor nanoparticle (S05) produced at a synthesis temperature of 180° C.

### Examples 7 to 11, and Examples 18 and 19

Indium phosphide was synthesized by electrospray at a voltage shown in Table 2 and an outer shell (shell layer) of zinc sulfide was formed on a surface of the indium phosphide synthesized, by use of the producing method of the first embodiment, and thereafter a fluorescence spectrum was measured. Indium chloride and tris(dimethylamino)phosphine were used for raw materials, and oleylamine was used for a dispersant.

The Examples were performed as follows. First, 0.3 g of indium chloride was weighed in a reaction container made of glass, and 5 mL of oleylamine was added thereto and mixed therewith. The operation was performed under a dry nitrogen atmosphere in order to prevent moisture absorption of the indium chloride. Subsequently, heating to 120° C. was made in an oil bath with nitrogen being allowed to flow through the reaction container, and the indium chloride was dissolved in the oleylamine. Subsequently, the reaction container was heated to 180° C. in an oil bath, and 1.05 mL of tris(dimethylamino)phosphine (at a rate of 0.050 mL/min for 21 minutes) was sprayed by electrospray from a stainless tube (spray unit) whose tip was adapted to be located at a distance of 3.5 cm from the liquid level and which had an inner diameter of 0.5 mm. The spray voltage was a value shown in Table 2. Thereafter, the resultant was cooled to room temperature, thereby providing an indium phosphide-containing solution sample.

In order to facilitate the comparison of fluorescent properties, 0.7 g of zinc stearate, 2.6 mL of dodecanethiol and 2.4 mL of 1-octadecene as a solvent were added to 1 mL of each solution sample obtained as described above, and the resultant was heated in an autoclave at 180° C. for 20 hours, thereby forming an outer shell (shell layer) of zinc sulfide on the surface of the indium phosphide. Thereafter, the resultant was cooled to room temperature, thereby providing a solution sample containing each indium phosphide (S08 to S12, and S19 and S20) where the outer shell of zinc sulfide was formed on the surface.

The fluorescence peak wavelength and the half-value width were measured in the same manner as in Examples 1 to 6 described above.

The results are shown in Table 2.

TABLE 2

| | Sample | Spray voltage | Fluorescence peak | Half-value |
|---|---|---|---|---|
| | number | kV | wavelength nm | width nm |
| Example 7 | S08 | 2.0 | 520 | 99 |
| Example 8 | S09 | 4.0 | 515 | 97 |
| Example 9 | S10 | 6.0 | 505 | 78 |
| Example 10 | S11 | 8.0 | 490 | 55 |
| Example 11 | S12 | 10.0 | 487 | 51 |
| Example 18 | S19 | 0.0 | 567 | 71 |
| Example 19 | S20 | 1.0 | 545 | 83 |

As shown in Table 2, the fluorescence peak wavelength and the half-value width of the fluorescence obtained from each of the semiconductor nanoparticles (S08 to S12, S19 and S20) produced in Example 7 to Example 11, and Examples 18 and 19 were varied due to application of spray voltage and furthermore were also varied due to the change in the magnitude of spray voltage.

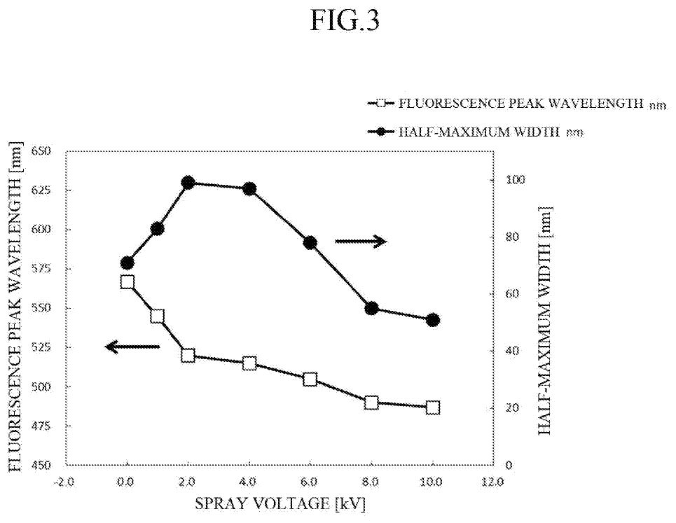

In particular, as illustrated in FIG. 3, fluorescence at 525±20 nm was obtained in measurement of a fluorescence spectrum of each of the semiconductor nanoparticles (S08 to S10 and S20) produced at a spray voltage of from 1.0 kV to 6.0 kV.

The half-value width was expanded due to a lowered spray voltage in a range of from 2.0 kV to 10.0 kV.

It has been presumed from the foregoing that the spray voltage is preferably from 1.0 kV to less than 8.0 kV from the viewpoint of providing fluorescence at 525±20 nm and the spray voltage is preferably less than 2.0 kV or 4.0 kV or more, more preferably from 6.0 kV to 10.0 kV from the viewpoint of a decrease in half-value width.

### Examples 12 to 17

Indium phosphide was synthesized at a molar ratio of an indium atom and a phosphorus atom, corresponding to a molar ratio of indium and phosphorus (molar ratio in raw materials, indium atom:phosphorus atom) shown in Table 3 and an outer shell (shell layer) of zinc sulfide was formed on a surface of the indium phosphide synthesized, by use of the producing method of the first embodiment, and thereafter a fluorescence spectrum was measured. Indium chloride and tris(dimethylamino)phosphine were used for such raw materials, and oleylamine was used for a dispersant.

The Examples were performed as follows. First, 0.3 g of indium chloride was weighed in a reaction container made of glass, and 5 mL of oleylamine was added thereto and mixed therewith. The operation was performed under a dry nitrogen atmosphere in order to prevent moisture absorption of the indium chloride. Subsequently, heating to 120° C. was made in an oil bath with nitrogen being allowed to flow through the reaction container, and the indium chloride was dissolved in the oleylamine. Subsequently, the reaction container was heated to 180° C. in an oil bath, and tris(dimethylamino)phosphine was sprayed by electrospray at a constant feeding rate such that the molar ratio of indium and phosphorus after 21 minutes was a value shown in Table 3, from a stainless tube (spray unit) whose tip was adapted to be located at a distance of 3.5 cm from the liquid level and which had an inner diameter of 0.5 mm. The spray voltage was 6.0 kV. Thereafter, the resultant was cooled to room temperature, thereby providing an indium phosphide-containing solution sample.

In order to facilitate the comparison of fluorescent properties, 0.7 g of zinc stearate, 2.6 mL of dodecanethiol and 2.4 mL of 1-octadecene as a solvent were added to 1 mL of each solution sample obtained as described above, and the resultant was heated in an autoclave at 180° C. for 20 hours, thereby forming an outer shell (shell layer) of zinc sulfide on the surface of the indium phosphide. Thereafter, the resultant was cooled to room temperature, thereby providing a solution sample containing each indium phosphide (S13 to S18) where the outer shell of zinc sulfide was formed on the surface.

The fluorescence peak wavelength and the half-value width were measured in the same manner as in Examples 1 to 6 described above.

The results are shown in Table 3.

TABLE 3

| | | Molar ratio of | | |
|---|---|---|---|---|
| | Sample | indium and | Fluorescence peak | Half-value |
| | number | phosphorus | wavelength nm | width nm |
| Example 12 | S13 | 1:1 | 541 | 96 |
| Example 13 | S14 | 1:2 | 533 | 99 |
| Example 14 | S15 | 1:4 | 505 | 78 |
| Example 15 | S16 | 1:6 | 530 | 86 |
| Example 16 | S17 | 1:8 | 556 | 97 |
| Example 17 | S18 | 1:16 | 561 | 86 |

As shown in Table 3, the fluorescence peak wavelength and the half-value width of the fluorescence obtained from each of the semiconductor nanoparticles (S13 to S18) produced in Example 12 to Example 17 were varied depending on the molar ratio of indium and phosphorus in synthesis.

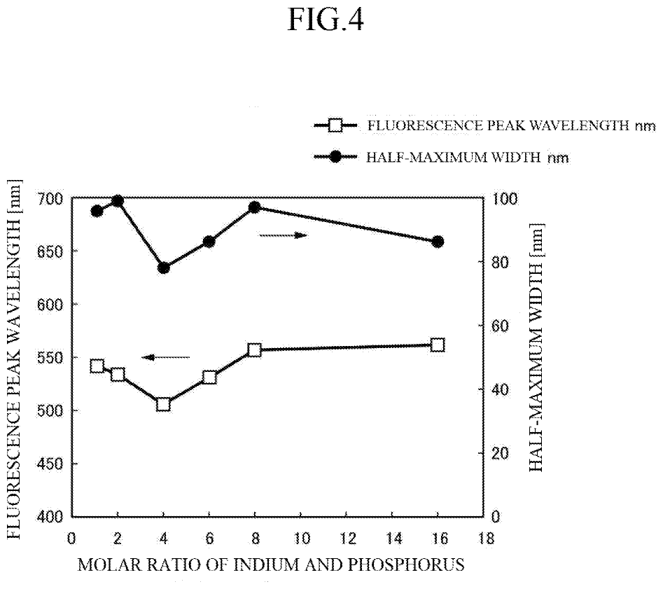

In particular, as illustrated in FIG. 4, fluorescence at 525±20 nm was obtained in measurement of a fluorescence spectrum of each of the semiconductor nanoparticles (S13 to S16) produced at a molar ratio of indium and phosphorus of 1 (indium):1 to 6 (phosphorus).

The half-value width was expanded due to an increase or decrease from a ratio of 1 (indium):4 (phosphorus).

The affection of the ratio with respect to the fluorescence peak wavelength and the half-value width was remarkably reduced by a ratio of 1 (indium):more than 8 (phosphorus). It has been thus presumed that the molar ratio of indium and phosphorus is preferably a ratio of 1 (indium):less than 8 (phosphorus) and is particularly preferably a ratio of 1 (indium):more than 2 but less than 6 (phosphorus) from the viewpoint of a decrease in half-value width with respect to the method of producing a semiconductor nanoparticle of the embodiment.

### Examples 20 to 25

Indium phosphide was synthesized with a spray unit having a spray port having a diameter shown in Table 4, for electrospray, and an outer shell (shell layer) of zinc sulfide was formed on a surface of the indium phosphide synthesized, by use of the producing method of the first embodiment, and thereafter a fluorescence spectrum was measured. Indium chloride and tris(dimethylamino)phosphine were used for raw materials, and oleylamine was used for a dispersant.

The Examples were performed as follows. First, 0.3 g of indium chloride was weighed in a reaction container made of glass, and 5 mL of oleylamine was added thereto and mixed therewith. The operation was performed under a dry nitrogen atmosphere in order to prevent moisture absorption of the indium chloride. Subsequently, heating to 120° C. was made in an oil bath with nitrogen being allowed to flow through the reaction container, and the indium chloride was dissolved in the oleylamine. Subsequently, the reaction container was heated to 180° C. in an oil bath, and tris(dimethylamino)phosphine was sprayed by electrospray from a stainless tube (spray unit) whose tip was adapted to be located at a distance of 3.5 cm from the liquid level and which had an inner diameter of from 0.08 to 0.80 mm, at a constant feeding rate (0.050 mL/min) for 21 minutes. The spray voltage was 6.0 kV. Thereafter, the resultant was cooled to room temperature, thereby providing an indium phosphide-containing solution sample.

In order to facilitate the comparison of fluorescent properties, 0.7 g of zinc stearate, 2.6 mL of dodecanethiol and 2.4 mL of 1-octadecene as a solvent were added to 1 mL of each solution sample obtained as described above, and the resultant was heated in an autoclave at 180° C. for 20 hours, thereby forming an outer shell (shell layer) of zinc sulfide on the surface of the indium phosphide. Thereafter, the resultant was cooled to room temperature, thereby providing a solution sample containing each indium phosphide (S21 to S26) where the outer shell of zinc sulfide was formed on the surface.

The fluorescence peak wavelength and the half-value width were measured in the same manner as in Examples 1 to 6 described above.

The results are shown in Table 4.

TABLE 4

| | Sample | Diameter of | Fluorescence peak | Half-value |
|---|---|---|---|---|
| | number | spray port mm | wavelength nm | width nm |
| Example 20 | S21 | 0.08 | 508 | 67 |
| Example 21 | S22 | 0.13 | 513 | 63 |
| Example 22 | S23 | 0.25 | 517 | 58 |
| Example 23 | S24 | 0.40 | 526 | 57 |
| Example 24 | S25 | 0.60 | 534 | 61 |
| Example 25 | S26 | 0.80 | 564 | 72 |

As shown in Table 4, the fluorescence peak wavelength and the half-value width of the fluorescence obtained from each of the semiconductor nanoparticles (S21 to S26) produced in Example 20 to Example 25 were varied depending on the diameter of the spray port (the width of the spray port) used in synthesis.

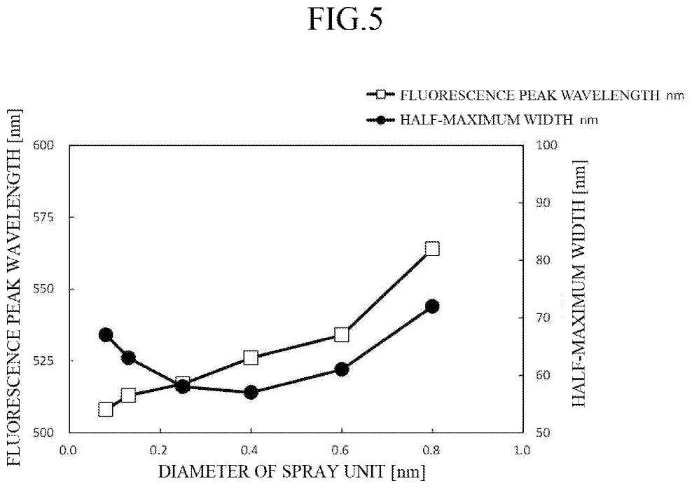

In particular, as illustrated in FIG. 5, fluorescence at 525±20 nm was obtained in measurement of a fluorescence spectrum of each of the semiconductor nanoparticles (S21 to S25) produced at a diameter of the spray port used, of from 0.08 mm to 0.60 mm.

The half-value width was changed in numerical value in a U-shaped manner, and a particularly narrow half-value width was obtained at a diameter of the spray port, of from 0.25 mm to 0.40 mm.

It has thus been presumed that the diameter of the spray port is preferably 0.60 mm or less and is particularly preferably from 0.25 mm to 0.40 mm from the viewpoint of a decrease in half-value width with respect to the method of producing a semiconductor nanoparticle of the embodiment.

The disclosure of Japanese Patent Application No. 2017-11180 filed on Jan. 25, 2017 is herein incorporated by reference in its entirety.

All documents, patent applications, and technical standards described herein are herein incorporated by reference, as if each individual document, patent application, and technical standard were specifically and individually indicated to be incorporated by reference.

### REFERENCE SIGNS LIST

1 supply source
2 spray unit
3 opposite electrode
4 power source
5 reactor
10 production apparatus

1. A method of producing an indium- and phosphorus-containing semiconductor nanoparticle, the method comprising:
preparing an indium-containing liquid (1) and a phosphorus-containing liquid (2), and
spraying one of the liquid (1) or the liquid (2) from a spray unit in an inert gas and bringing a sprayed liquid droplet into contact with another liquid of the liquid (1) or the liquid (2), which is not sprayed, thereby mixing the liquid (1) and the liquid (2) to allow indium and phosphorus to react.

2. A method of producing an indium- and phosphorus-containing semiconductor nanoparticle, the method comprising:
spraying an indium- and phosphorus-containing liquid (3) from a spray unit in an inert gas and bringing a sprayed liquid droplet into contact with a liquid (4), thereby mixing the liquid (3) and the liquid (4) to allow indium and phosphorus to react.

3. The method of producing an indium- and phosphorus-containing semiconductor nanoparticle according to claim 1, wherein the spraying is performed by electrospray.

4. The method of producing an indium- and phosphorus-containing semiconductor nanoparticle according to claim 3, wherein the spraying by the electrospray is performed with a potential difference being provided between a first electrode, which forms at least a part of a flow path for a liquid to be sprayed, or which is attached to at least a part of the flow path, and a second electrode which is disposed at a position where the liquid droplet is brought into contact with a liquid to be sprayed.

5. The method of producing an indium- and phosphorus-containing semiconductor nanoparticle according to claim 4, wherein the potential difference between the first electrode and the second electrode is from 0.3 kV to 30 kV, as an absolute value.

6. The method of producing an indium- and phosphorus-containing semiconductor nanoparticle according to claim 1, wherein a diameter of the sprayed liquid droplet is from 0.1 μm to 100 μm.

7. The method of producing an indium- and phosphorus-containing semiconductor nanoparticle according to claim 1, wherein:
the semiconductor nanoparticle has a core particle comprising indium and phosphorus, and
a layer comprising a Group 16 element and at least one of a Group 12 element or a Group 13 element is formed on at least a part of a surface of the core particle, after formation of the core particle.

8. The method of producing an indium- and phosphorus-containing semiconductor nanoparticle according to claim 1, wherein a width of a spray port in the spray unit is from 0.03 mm to 2.0 mm.

9. The method of producing an indium- and phosphorus-containing semiconductor nanoparticle according to claim 1, wherein a feeding rate of the liquid to be sprayed is from 0.001 mL/min to 1 mL/min with respect to one flow path provided with the spray unit.

10. The method of producing an indium- and phosphorus-containing semiconductor nanoparticle according to claim 1, wherein an indium- and phosphorus-containing liquid is heated in the reaction of indium and phosphorus.

11. The method of producing an indium- and phosphorus-containing semiconductor nanoparticle according to claim 10, wherein a heating temperature of the indium- and phosphorus-containing liquid is from 80° C. to 350° C.

12. The method of producing an indium- and phosphorus-containing semiconductor nanoparticle according to claim 1, wherein a molar ratio of an indium atom and a phosphorus atom (indium atom:phosphorus atom) in an indium- and phosphorus-containing liquid is from 1:1 to 1:16 after spraying of the liquid droplet.

13. The method of producing an indium- and phosphorus-containing semiconductor nanoparticle according to claim 2, wherein the spraying is performed by electrospray.

14. The method of producing an indium- and phosphorus-containing semiconductor nanoparticle according to claim 13, wherein the spraying by the electrospray is performed with a potential difference being provided between a first electrode, which forms at least a part of a flow path for a liquid to be sprayed, or which is attached to at least a part of the flow path, and a second electrode which is disposed at a position where the liquid droplet is brought into contact with a liquid to be sprayed.

15. The method of producing an indium- and phosphorus-containing semiconductor nanoparticle according to claim 14, wherein the potential difference between the first electrode and the second electrode is from 0.3 kV to 30 kV, as an absolute value.

16. The method of producing an indium- and phosphorus-containing semiconductor nanoparticle according to claim 2, wherein a diameter of the sprayed liquid droplet is from 0.1 μm to 100 μm.

17. The method of producing an indium- and phosphorus-containing semiconductor nanoparticle according to claim 2, wherein:
the semiconductor nanoparticle has a core particle comprising indium and phosphorus, and
a layer comprising a Group 16 element and at least one of a Group 12 element or a Group 13 element is formed on at least a part of a surface of the core particle, after formation of the core particle.

18. The method of producing an indium- and phosphorus-containing semiconductor nanoparticle according to claim 2, wherein a width of a spray port in the spray unit is from 0.03 mm to 2.0 mm.

19. The method of producing an indium- and phosphorus-containing semiconductor nanoparticle according to claim 2, wherein a feeding rate of the liquid to be sprayed is from 0.001 mL/min to 1 mL/min with respect to one flow path provided with the spray unit.

20. The method of producing an indium- and phosphorus-containing semiconductor nanoparticle according to claim 2, wherein an indium- and phosphorus-containing liquid is heated in the reaction of indium and phosphorus.
